(19) United States
(12) Patent Application Publication
(10) Pub. No.: US 2026/0089922 A1
(43) Pub. Date: Mar. 26, 2026

(54) SEMICONDUCTOR STRUCTURE AND METHOD OF FORMING THE SAME

(71) Applicant: NANYA TECHNOLOGY CORPORATION, New Taipei City (TW)

(72) Inventor: Jhen-Yu TSAI, New Taipei City (TW)

(21) Appl. No.: 18/890,773

(22) Filed: Sep. 20, 2024

(51) Int. Cl. H10B 12/00

(52) U.S. Cl. CPC H10B 12/34; H10B 12/053

(57) ABSTRACT

The present disclosure provides a semiconductor structure. The semiconductor structure includes a substrate and a word line. The word line is embedded in the substrate and includes a high work function layer and a low work function layer on the high work function layer, in which an average work function of the high work function layer is larger than an average work function of the low work function layer, the low work function layer includes a lower portion and an upper portion on the lower portion, and an average grain size of the lower portion is smaller than an average grain size of the upper portion.

### BACKGROUND

### Field of Invention

The present disclosure relates to a semiconductor structure and a method of forming the same.

### Description of Related Art

Word lines are used in semiconductor structures, such as dynamic random-access memory (DRAM) devices. To improve the electrical property of the word line, a dopant may be doped into the word line. However, the work functions of the materials in the word line may change when increasing the dopant concentration of the dopant, and undesired work functions may lead to gate-induced drain leakage (GIDL). Therefore, it is necessary to develop a novel word line and a novel method of forming the same to improve the electrical property of the word line and reduce the gate-induced drain leakage.

### SUMMARY

The present disclosure provides a semiconductor structure. The semiconductor structure includes a substrate and a word line. The word line is embedded in the substrate and includes a high work function layer and a low work function layer on the high work function layer, in which an average work function of the high work function layer is larger than an average work function of the low work function layer, the low work function layer includes a lower portion and an upper portion on the lower portion, and an average grain size of the lower portion is smaller than an average grain size of the upper portion.

In some embodiments, the average grain size of the lower portion is from 1 nm to 5 nm, and the average grain size of the upper portion is from 5 nm to 20 nm.

In some embodiments, an average work function of the lower portion is larger than an average work function of the upper portion.

In some embodiments, the average work function of the high work function layer is larger than an average work function of the lower portion.

In some embodiments, dopant concentrations in the lower portion and the upper portion are larger than 1×10²⁰ atoms/cm³.

In some embodiments, a ratio of a thickness of the lower portion to a thickness of the upper portion is from 1:1 to 1:10.

In some embodiments, the high work function layer is a metal layer and the low work function layer is a silicon-containing conductive layer.

In some embodiments, the semiconductor structure further includes a dielectric layer between the word line and the substrate.

In some embodiments, the semiconductor structure further includes a barrier layer between the high work function layer and the low work function layer.

In some embodiments, the semiconductor structure further includes a dielectric layer on the low work function layer.

The present disclosure also provides a method of forming a semiconductor structure. The method includes the following operations. A first work function layer and a second work function layer on the first work function layer are formed in a trench of a substrate, in which the second work function layer includes a lower portion and an upper portion on the lower portion, the lower portion has a first average grain size, and the upper portion has a second average grain size. The upper portion is annealed by a laser annealing to change the second average grain size to a third average grain size, in which the third average grain size is larger than the first average grain size.

In some embodiments, after annealing the upper portion, an average work function of the first work function layer is larger than an average work function of the second work function layer.

In some embodiments, the first average grain size and the second average grain size are the same.

In some embodiments, the laser annealing is performed with an intensity from 250 mJ/cm² to 400 mJ/cm².

In some embodiments, a ratio of a thickness of the lower portion to a thickness of the upper portion is from 1:1 to 1:10.

In some embodiments, forming the second work function layer includes in-situ doping a dopant with a dopant concentration larger than 1×10²⁰ atoms/cm³.

In some embodiments, forming the second work function layer includes using a precursor gas, and the precursor gas includes silane, disilane, dichlorosilane, or combinations thereof.

In some embodiments, the method further includes forming a dielectric layer on a sidewall of the trench before forming the first work function layer and the second work function layer.

In some embodiments, the method further includes forming a barrier layer on the first work function layer after forming the first work function layer and before forming the second work function layer.

In some embodiments, the method further includes forming a dielectric layer on the second work function layer after annealing the upper portion.

### BRIEF DESCRIPTION OF THE DRAWINGS

The present disclosure can be more fully understood by reading the following detailed description of the embodiments, with reference made to the accompanying figures as follows.

FIG. 1 is a cross-sectional view of a portion of a word line embedded in a substrate in a semiconductor structure according to some embodiments of the present disclosure.

FIG. 2 is a flow chart of a method of forming a semiconductor structure according to some embodiments of the present disclosure.

FIGS. 3 to 7 are cross-sectional views of portions of the structures in the stages of forming the semiconductor structure according to some embodiments of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated at 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

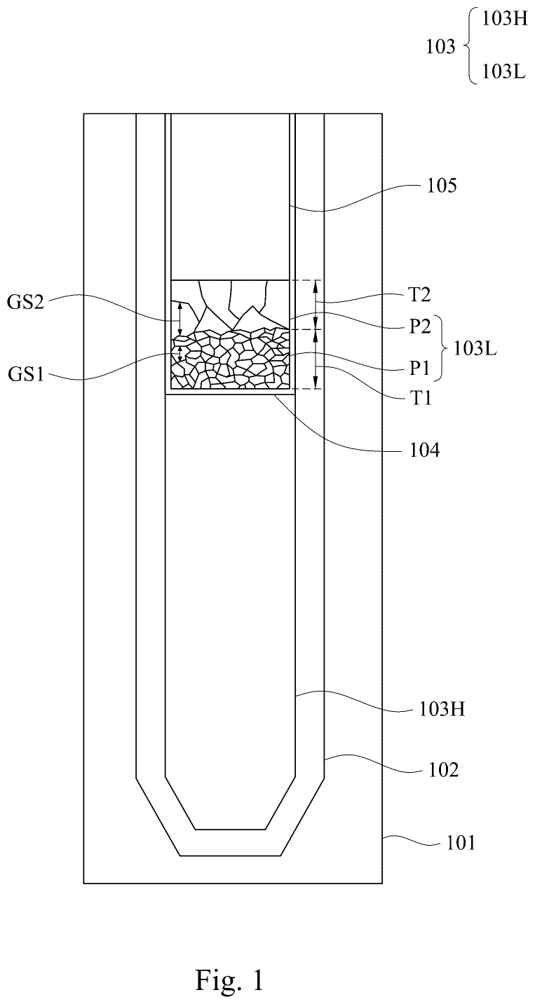

The present disclosure provides a semiconductor structure. The semiconductor structure includes a substrate 101 and a word line 103, as shown in FIG. 1. The word line 103 is embedded in the substrate 101 and includes a high work function layer 103H and a low work function layer 103L on the high work function layer 103H, in which an average work function of the high work function layer 103H is larger than an average work function of the low work function layer 103L, the low work function layer 103L includes a lower portion P1 and an upper portion P2 on the lower portion P1, and an average grain size GS1 of the lower portion P1 is smaller than an average grain size GS2 of the upper portion P2. Since the average grain size GS1 of the lower portion P1 is smaller than the average grain size GS2 of the upper portion P2, undesired void that may induce current leakage and the significant drop of the resistance are reduced in the low work function layer 103L compared with having a larger average grain size in the lower portion P1 than in the upper portion P2. Moreover, the larger average grain size in the upper portion P2 reduces the average work function of the low work function layer 103L, such that more dopant can be doped into the low work function layer 103L but not increase the average work function of the low work function layer 103L, thereby improving the electrical property of the word line 103. In addition, the lower work function of the low work function layer 103L than the high work function layer 103H can reduce the gate-induced drain leakage. The semiconductor structure of the present disclosure is described in more detail with the following embodiments.

Firstly, the substrate 101 is described. In some embodiments, the substrate 101 is a semiconductor substrate and may include any suitable semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof.

Secondly, the word line 103 is described. In some embodiments, the word line 103 is embedded in the substrate 101 to control the switches of the gates in the transistors. In some embodiments, the low work function layer 103L of the word line 103 is used as the gate, and compared with excluding the high work function layer 103H, the word line 103 including the high work function layer 103H reduces the gate-induced drain leakage. In some embodiments, the semiconductor structure further includes a source and a drain beside the gate. The low work function layer 103L is disposed on the high work function layer 103H, and the average work function of the high work function layer 103H is larger than the average work function of the low work function layer 103L. In some embodiments, the average work function of the high work function layer 103H is preferably from 4.3 eV to 4.9 eV, for example, 4.3 eV, 4.4 eV, 4.5 eV, 4.6 eV, 4.7 eV, 4.8 eV, or 4.9 eV. In some embodiments, the average work function of the low work function layer 103L is preferably from 4.0 eV to 4.6 eV, for example, 4.0 eV, 4.1 eV, 4.2 eV, 4.3 eV, 4.4 eV, 4.5 eV, or 4.6 eV. In some embodiments, the high work function layer 103H and the low work function layer 103L are conductive. In some embodiments, the high work function layer 103H is a metal layer, for example, including tungsten, and the low work function layer 103L is a silicon-containing conductive layer, for example, including polysilicon. In some embodiments, the low work function layer 103L is crystalline.

The low work function layer 103L includes the lower portion P1 and the upper portion P2 on the lower portion P1, and the average grain size GS1 of the lower portion P1 is smaller than the average grain size GS2 of the upper portion P2. In some embodiments, the grain size is different than the crystallite size and the particle size, and the sizes of the grains are defined by the boundaries between the grains, in which the boundaries are between the grains where the orientation of the crystallites is changed at the boundaries. It is found that when the grain size is small in a material, the work function of the material may increase when more dopant is doped into the material. On the contrary, when the grain size is large in a material, the work function of the material may decrease when more dopant is doped into the material. Therefore, to have a smaller grain size to reduce the current leakage in the low work function layer 103L, it is better to also have a portion of the low work function layer 103L having a larger grain size to reduce the average work function of the low work function layer 103L, such that the work function of the low work function layer 103L may be smaller than the work function of the high work function layer 103H to reduce the gate-induced current leakage. In addition to reducing the current leakage and having a smaller average work function in the low work function layer 103L, in the present disclosure, the smaller average grain size in the lower portion P1 of the low work function layer 103L and the larger average grain size in the upper portion P2 of the low work function layer 103L also improve the electrical property of the word line 103, for example, decreasing the resistance, further decreasing the current leakage, and so on.

In some embodiments, the average grain size GS1 of the lower portion P1 of the low work function layer 103L is preferably from 1 nm to 5 nm, for example, 1 nm, 2 nm, 3 nm, 4 nm, or 5 nm. In some embodiments, the average grain size GS2 of the upper portion P2 of the low work function layer 103L is preferably from 5 nm to 20 nm, for example, 5 nm, 10 nm, 15 nm, or 20 nm. In some embodiments, an average work function of the lower portion P1 of the low work function layer 103L is larger than an average work function of the upper portion P2 of the low work function layer 103L. In some embodiments, the average work function of the lower portion P1 of the low work function layer 103L is preferably from 4.1 eV to 4.7 eV, for example, 4.1 eV, 4.2 eV, 4.3 eV, 4.4 eV, 4.5 eV, 4.6 eV, or 4.7 eV, and the average work function of the upper portion P2 of the low work function layer 103L is preferably from 3.9 eV to 4.5eV, for example, 3.9 eV, 4.0 eV, 4.1 eV, 4.2 eV, 4.3 eV, 4.4 eV, or 4.5 eV. In some embodiments, the average work function of the high work function layer 103H is larger than the average work function of the lower portion P1 of the low work function layer 103L. In some embodiments, the work function of the word line 103 decreases from the high work function layer 103H, through the lower portion P1 of the low work function layer 103L, and to the upper portion P2 of the low work function layer 103L.

In some embodiments, the low work function layer 103L (e.g., the lower portion P1 and the upper portion P2) is doped with an N-type dopant or a P-type dopant to improve the electrical property of the word line 103. In some embodiments, the dopant doped in the lower portion P1 of the low work function layer 103L and the dopant doped in the upper portion P2 of the low work function layer 103L are the same. In some embodiments, the dopant concentration in the low work function layer 103L (e.g., in the lower portion P1 and in the upper portion P2) is preferably larger than 1×10²⁰ atoms/cm³ and preferably smaller than 1×10²² atoms/cm³. In some embodiments, the dopant concentration in the lower portion P1 of the low work function layer 103L and the dopant concentration in the upper portion P2 of the low work function layer 103L are substantially the same.

In some embodiments, a ratio of a thickness T1 of the lower portion P1 of the low work function layer 103L to a thickness T2 of the upper portion P2 of the low work function layer 103L is preferably from 1:1 to 1:10, for example, 1:1, 1:1.5, 1:2.5, 1:5, 1:7.5, or 1:10. In some embodiments, the thickness T2 of the upper portion P2 of the low work function layer 103L is more preferably larger than the thickness T1 of the lower portion P1 of the low work function layer 103L. In some embodiments, the thickness T1 of the lower portion P1 of the low work function layer 103L is preferably smaller than 10 nm.

In some embodiments, the semiconductor structure further includes a dielectric layer 102 between the word line 103 and the substrate 101 to provide the electrical isolation for the word line 103. In some embodiments, the dielectric layer 102 includes any suitable dielectric material, for example, silicon oxide, silicon nitride, or a combination thereof.

In some embodiments, the semiconductor structure further includes a barrier layer 104 between the high work function layer 103H and the low work function layer 103L to avoid the high work function layer 103H reacting with the low work function layer 103L. In some embodiments, the barrier layer 104 covers the whole upper surface of the high work function layer 103H and the whole lower surface of the low work function layer 103L. In some embodiments, the barrier layer 104 extends to cover the side surface of the low work function layer 103L. In some embodiments, the barrier layer 104 is on the dielectric layer 102. In some embodiments, the material of the barrier layer 104 is different than the material of the dielectric layer 102. In some embodiments, the material of the barrier layer 104 is the same as the material of the dielectric layer 102. In some embodiments, the barrier layer 104 includes silicon oxide, titanium nitride, or a combination thereof.

In some embodiments, the semiconductor structure further includes a dielectric layer 105 on the low work function layer 103L to provide the electrical isolation for the word line 103. In some embodiments, the dielectric layer 105 covers the whole upper surface of the low work function layer 103L. In some embodiments, the dielectric layer 102 between the word line 103 and the substrate 101 extends to be between the dielectric layer 105 and the substrate 101. In some embodiments, the dielectric layer 105 includes any suitable dielectric material, for example, silicon oxide, silicon nitride, or a combination thereof.

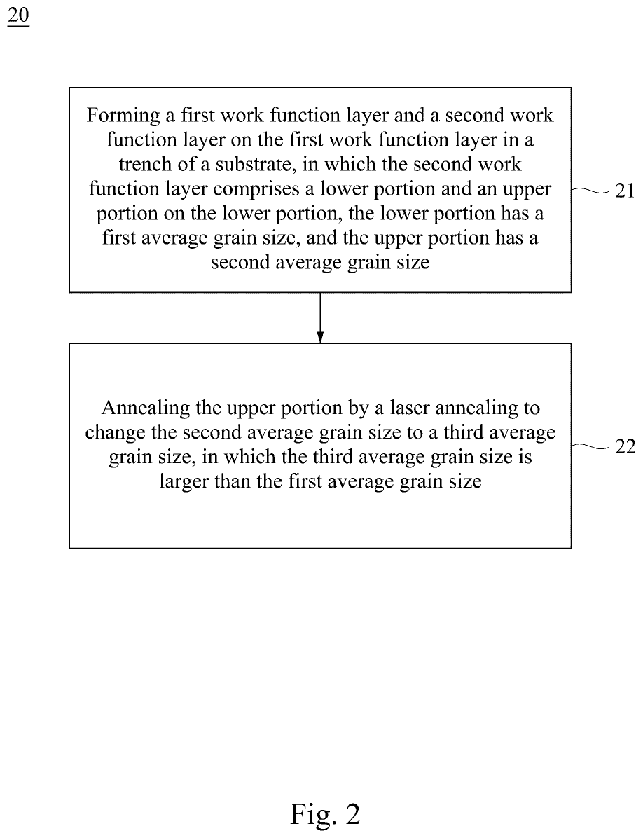

The present disclosure also provides a method 20 of forming the semiconductor structure described above. When reading the flow chart of the method 20 shown in FIG. 2, please also refer to FIGS. 1 and 3 to 7 for more detail. The method 20 includes an operation 21 to an operation 22. The operation 21 includes forming a first work function layer 103H′ and a second work function layer 103L′ on the first work function layer 103H′ in a trench 201 of a substrate 101, in which the second work function layer 103L′ includes a lower portion P1′ and an upper portion P2′ on the lower portion P1′, the lower portion P1′ has a first average grain size S1, and the upper portion P2′ has a second average grain size S2. The operation 22 includes annealing the upper portion P2′ by a laser annealing to change the second average grain size S2 to a third average grain size S3, in which the third average grain size S3 is larger than the first average grain size S1. The method 20 of the present disclosure is described in more detail with the following embodiments.

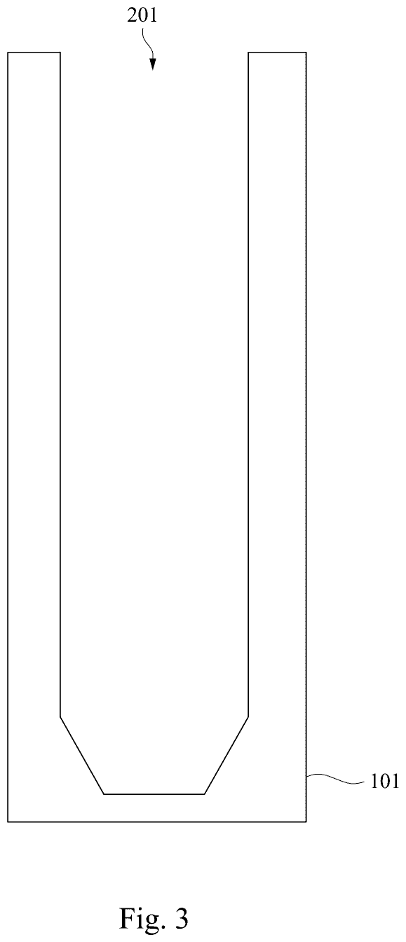

See FIG. 3. Before performing the operation 21, in some embodiments, the method 20 further includes forming the trench 201 in the substrate 101 by any suitable etching method, for example, by a dry etching method or a wet etching method. In some embodiments, the substrate 101 is substantially the same as the substrate 101 in the semiconductor structure described above and the detail may not be repeated herein.

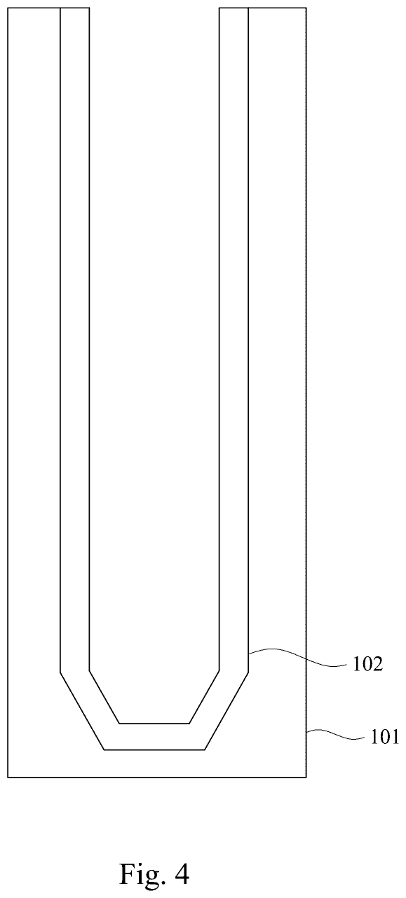

See FIG. 4. Before performing the operation 21, in some embodiments, the method 20 further includes forming the dielectric layer 102 on a sidewall of the trench 201 by any suitable deposition method, for example, by a chemical vapor deposition method or a physical vapor deposition method. In some embodiments, the dielectric layer 102 is formed on the exposed surface of the trench 201. In some embodiments, the dielectric layer 102 is conformally formed on the trench 201. In some embodiments, the dielectric layer 102 is substantially the same as the dielectric layer 102 in the semiconductor structure described above and the detail may not be repeated herein.

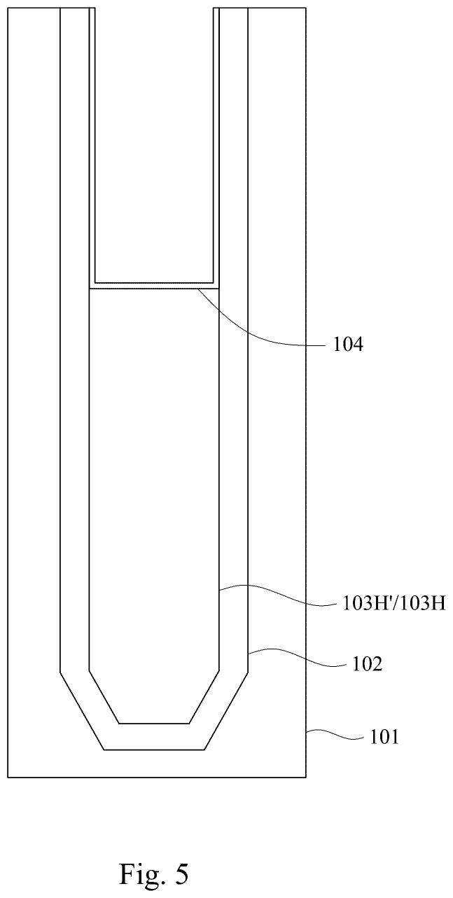

See FIG. 5. The operation 21 includes forming the first work function layer 103H′ in the trench 201 of the substrate 101 by any suitable deposition method, for example, by a chemical vapor deposition method or a physical vapor deposition method. In some embodiments, the first work function layer 103H′ is substantially the same as the high work function layer 103H in the semiconductor structure described above and the detail may not be repeated herein. In some embodiments, the method 20 further includes forming the barrier layer 104 by any suitable deposition method, for example, by a chemical vapor deposition method or a physical vapor deposition method, on the first work function layer 103H′ after forming the first work function layer 103H′. In some embodiments, the barrier layer 104 is substantially the same as the barrier layer 104 in the semiconductor structure described above and the detail may not be repeated herein.

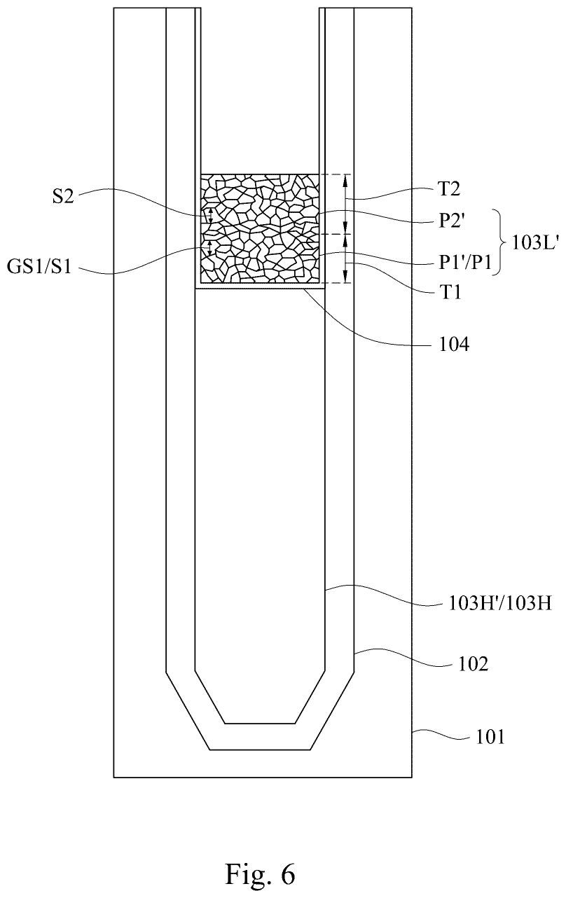

See FIG. 6. The operation 21 further includes forming the second work function layer 103L′ on the first work function layer 103H′ in the trench 201 of the substrate 101. In some embodiments, the second work function layer 103L′ will become the low work function layer 103L substantially the same as the low work function layer 103L in the semiconductor structure described above after performing the operation 22 described later. In some embodiments, forming the second work function layer 103L′ includes using a precursor gas, in which the precursor gas reacts to from the second work function layer 103L′. In some embodiments, the precursor gas includes silane, disilane, dichlorosilane, or combinations thereof. In some embodiments, a flow rate of the precursor gas is preferably from 200 sccm to 1000 sccm, for example, 200 sccm, 400 sccm, 600 sccm, 800 sccm, or 1000 sccm. In some embodiments, forming the second work function layer 103L′ is performed at a pressure preferably from 10 Torr to 100 Torr, for example, 10 Torr, 20 Torr, 40 Torr, 60 Torr, 80 Torr, or 100 Torr. In some embodiments, forming the second work function layer 103L′ is performed at a temperature preferably from 500° C. to 900° C., for example, 500° C., 600° C., 700° C., 800° C., or 900° C. The flow rate, the pressure, and the temperature may affect the grain size of the second work function layer 103L′.

In some embodiments, forming the second work function layer 103L′ includes in-situ doping a dopant with a dopant concentration larger than 1×10²⁰ atoms/cm³ and smaller than 1×10²² atoms/cm³ to improve the electrical property of the word line formed after the operation 22. In some embodiments, the dopant is an N-type dopant or a P-type dopant. In some embodiments, the barrier layer 104 is formed before forming the second work function layer 103L′.

The second work function layer 103L′ includes the lower portion P1′ and the upper portion P2′ on the lower portion P1′. In some embodiments, the lower portion P1′ is substantially the same as the lower portion P1 in the semiconductor structure described above and the detail may not be repeated herein. For example, the lower portion P1′ has the first average grain size S1 substantially the same as the average grain size GS1 of the lower portion P1 described above. In some embodiments, the upper portion P2′ will become the upper portion P2 substantially the same as the upper portion P2 in the semiconductor structure described above after performing the operation 22 described later. In some embodiments, before performing the operation 22, the upper portion P2′ has the second average grain size S2, and in some embodiments, the first average grain size S1 and the second average grain size S2 are substantially the same. In some embodiments, the thickness T1 of the lower portion P1′ and the thickness T2 of the upper portion P2′ are substantially the same as the thickness T1 of the lower portion P1 and the thickness T2 of the upper portion P2 described above, and in some embodiments, the ratio of the thickness T1 of the lower portion P1′ to the thickness T2 of the upper portion P2′ is also preferably from 1:1 to 1:10, for example, 1:1, 1:1.5, 1:2.5, 1:5, 1:7.5, or 1:10.

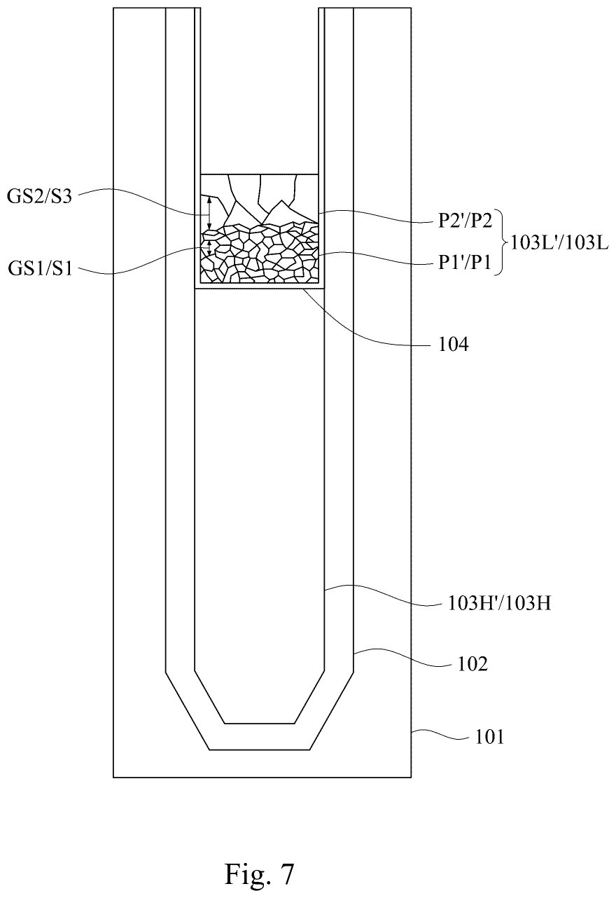

See FIG. 7. The operation 22 includes annealing the upper portion P2′ of the second work function layer 103L′ by the laser annealing to change the second average grain size S2 to the third average grain size S3, in which the third average grain size S3 is larger than the first average grain size S1 and the second average grain size S2. By performing the annealing, the orientation of the crystallites may rearrange in the upper portion P2′ of the second work function layer 103L′ to change the boundaries of the grains and become bigger grain sizes. For the advantages of having the smaller average grain size in the lower portion of the second work function layer (i.e., the low work function layer) and the larger average grain size in the upper portion of the second work function layer (i.e., the low work function layer), please refer to the description above. After the operation 22, the low work function layer 103L and the upper portion P2 described above are formed. For example, the average work function of the first work function layer 103H′ is larger than the average work function of the second work function layer 103L′ after annealing the upper portion P2′ of the second work function layer 103L′, and the third average grain size S3 is substantially the same as the average grain size GS2 of the upper portion P2. In some embodiments, the laser annealing is performed with an intensity preferably from 250 mJ/cm² to 400 mJ/cm², for example, 250 mJ/cm², 300 mJ/cm², 350 mJ/cm², or 400 mJ/cm².

See FIG. 1. In some embodiments, the method 20 further includes forming the dielectric layer 105 on the second work function layer 103L′ after annealing the upper portion P2′ of the second work function layer 103L′. In some embodiments, the dielectric layer 105 is substantially the same as the dielectric layer 105 in the semiconductor structure described above and the detail may not be repeated herein. After forming the dielectric layer 105, the semiconductor structure described in FIG. 1 is formed.

The semiconductor structure of the present disclosure and the semiconductor structure formed by the method of the present disclosure improve the performance of the word line, for example, reducing the current leakage, reducing the gate-induced drain leakage, increasing the dopant in the word line, reducing the resistance, and so on.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A semiconductor structure, comprising:
a substrate; and
a word line embedded in the substrate and comprising a high work function layer and a low work function layer on the high work function layer, wherein an average work function of the high work function layer is larger than an average work function of the low work function layer, the low work function layer comprises a lower portion and an upper portion on the lower portion, and an average grain size of the lower portion is smaller than an average grain size of the upper portion.

2. The semiconductor structure of claim 1, wherein the average grain size of the lower portion is from 1 nm to 5 nm, and the average grain size of the upper portion is from 5 nm to 20 nm.

3. The semiconductor structure of claim 1, wherein an average work function of the lower portion is larger than an average work function of the upper portion.

4. The semiconductor structure of claim 1, wherein the average work function of the high work function layer is larger than an average work function of the lower portion.

5. The semiconductor structure of claim 1, wherein dopant concentrations in the lower portion and the upper portion are larger than 1×10²⁰ atoms/cm³.

6. The semiconductor structure of claim 1, wherein a ratio of a thickness of the lower portion to a thickness of the upper portion is from 1:1 to 1:10.

7. The semiconductor structure of claim 1, wherein the high work function layer is a metal layer and the low work function layer is a silicon-containing conductive layer.

8. The semiconductor structure of claim 1, further comprising a dielectric layer between the word line and the substrate.

9. The semiconductor structure of claim 1, further comprising a barrier layer between the high work function layer and the low work function layer.

10. The semiconductor structure of claim 1, further comprising a dielectric layer on the low work function layer.

11. A method of forming a semiconductor structure, comprising:
forming a first work function layer and a second work function layer on the first work function layer in a trench of a substrate, wherein the second work function layer comprises a lower portion and an upper portion on the lower portion, the lower portion has a first average grain size, and the upper portion has a second average grain size; and
annealing the upper portion by a laser annealing to change the second average grain size to a third average grain size, wherein the third average grain size is larger than the first average grain size.

12. The method of claim 11, wherein after annealing the upper portion, an average work function of the first work function layer is larger than an average work function of the second work function layer.

13. The method of claim 11, wherein the first average grain size and the second average grain size are the same.

14. The method of claim 11, wherein the laser annealing is performed with an intensity from 250 mJ/cm² to 400 mJ/cm².

15. The method of claim 11, wherein a ratio of a thickness of the lower portion to a thickness of the upper portion is from 1:1 to 1:10.

16. The method of claim 11, wherein forming the second work function layer comprises in-situ doping a dopant with a dopant concentration larger than 1×10²⁰ atoms/cm³.

17. The method of claim 11, wherein forming the second work function layer comprises using a precursor gas, and the precursor gas comprises silane, disilane, dichlorosilane, or combinations thereof.

18. The method of claim 11, further comprising forming a dielectric layer on a sidewall of the trench before forming the first work function layer and the second work function layer.

19. The method of claim 11, further comprising forming a barrier layer on the first work function layer after forming the first work function layer and before forming the second work function layer.

20. The method of claim 11, further comprising forming a dielectric layer on the second work function layer after annealing the upper portion.
